(19) United States
(12) Patent Application Publication
(10) Pub. No.: US 2013/0119234 A1
(43) Pub. Date: May 16, 2013

(54) UNIT PIXEL AND THREE-DIMENSIONAL IMAGE SENSOR INCLUDING THE SAME

(71) Applicants: Yong-Jei LEE, Seongnam-si (KR); Young-Gu JIN, Osan-si (KR); Tae-Yon LEE, Seoul (KR); Yoon-Dong PARK, Yongin-si (KR); Eric R. FOSSUM, Wolfeboro, NH (US)

(72) Inventors: Yong-Jei LEE, Seongnam-si (KR); Young-Gu JIN, Osan-si (KR); Tae-Yon LEE, Seoul (KR); Yoon-Dong PARK, Yongin-si (KR); Eric R. FOSSUM, Wolfeboro, NH (US)

(73) Assignee: SAMSUNG ELECTRONICS CO., LTD., Suwon-si (KR)

(21) Appl. No.: 13/615,424

(22) Filed: Sep. 13, 2012

(30) Foreign Application Priority Data
Nov. 14, 2011 (KR) 10-2011-0118393

(51) Int. Cl. H01L 27/146; H01L 31/103; H01L 31/105; H01L 31/101

(52) U.S. Cl. 250/208.1; 250/214 P

(57) ABSTRACT

A unit pixel of a three-dimensional image sensor includes a non-silicon photodetector and at least one readout circuit. The non-silicon photodetector is formed at a silicon substrate, and the non-silicon photodetector comprising at least one of non-silicon materials to generate a photocharge in response to incident light. The at least one readout circuit is formed at the silicon substrate, the at least one readout circuit outputs a sensing signal based on the photocharge, and the sensing signal generates depth information on a distance to an object.

### CROSS-REFERENCE TO RELATED APPLICATION

This application claims priority under 35 USC §119 to Korean Patent Application No. 10-2011-0118393, filed on Nov. 14, 2011, in the Korean Intellectual Property Office (KIPO), the contents of which are herein incorporated by reference in their entirety.

### BACKGROUND

1. Technical Field

Example embodiments relate generally to photo-sensing devices. More particularly, embodiments relate to a unit pixel of the photo-sensing device and a three-dimensional image sensor including the unit pixel.

2. Description of the Related Art

A photo-sensing device, i.e., an image sensor, is configured to convert optical signals, which provide image information and/or depth information of an object, to electrical signals. Research and development is in progress to enhance the quality of the image captured by the image sensor, i.e., a charge-coupled device (CCD) image sensor and a complementary metal oxide semiconductor (CMOS) image sensor. Further, research is in progress to improve performance of a three-dimensional image sensor. Improving performance of a three-dimensional image sensor would provide depth information or distance information representing a distance to an object in addition to the image information of the object.

A three-dimensional image sensor uses infrared light or near-infrared light as transmission light to obtain the depth information. Compared with color pixels for obtaining the image information, depth pixels have relatively low sensitivity and signal-to-noise ratio (SNR). Thus, it is relatively difficult to obtain the accurate depth information.

### SUMMARY

Some example embodiments provide a unit pixel of a three-dimensional image sensor. The three-dimensional image sensor may have enhanced quantum efficiency.

Some example embodiments provide a three-dimensional image sensor including a unit pixel. The unit pixel may have enhanced quantum efficiency.

According to an aspect of an example embodiment, a unit pixel of a three-dimensional image sensor includes a non-silicon photodetector and at least one readout circuit. The non-silicon photodetector is formed at a silicon substrate, and the non-silicon photodetector includes at least one of non-silicon materials to generate a photocharge in response to incident light. The at least one readout circuit is formed at the silicon substrate, the at least one readout circuit outputs a sensing signal based on the photocharge, and the sensing signal generates depth information on a distance to an object.

The non-silicon photodetector may be formed on a doped region in the at least one readout circuit. The non-silicon photodetector may be a photoconductor, which includes intrinsic germanium.

The non-silicon photodetector may include N-type germanium and P-type germanium and the non-silicon photodetector may form a PN junction diode.

The doped region may include N-type silicon, the non-silicon photodetector may include P-type germanium and intrinsic germanium, and the doped region and the non-silicon photodetector may form a PIN junction diode.

The non-silicon photodetector may include at least one of germanium, silicon germanium compound, indium gallium arsenide, amorphous silicon germanium compound, black silicon germanium compound, porous silicon germanium compound, germanium antimony telluride, indium gallium antimonide, indium arsenide, mercury cadmium telluride, silicide, transition metal silicide, selenide, telluride, and sulfide.

The non-silicon photodetector may include photosensitive semiconductor quantum dots.

The unit pixel may further include a buffer unit coupled between the non-silicon photodetector and the at least one readout circuit, and the buffer unit may be turned on and off in response to a buffer control signal.

The non-silicon photodetector may have higher quantum efficiency with respect to infrared light, than a quantum efficiency with respect to visible light.

The non-silicon photodetector may have higher quantum efficiency with respect to infrared light, than a quantum efficiency of a silicon photodetector.

The non-silicon photodetector may have higher quantum efficiency with respect to light having a wavelength between 800 nm and 1100 nm, than a quantum efficiency of a silicon photodetector.

The non-silicon photodetector may be formed at a recess in the silicon substrate, and the recess may be adjacent to the at least one readout circuit. The non-silicon photodetector may be formed on the at least one readout circuit.

According to another aspect of an example embodiment, a three-dimensional image sensor includes a light source module, a pixel array and an image signal processor. The light source module generates modulated transmission light having periodically-varying intensity. The pixel array includes a plurality of unit pixels configured to convert incident light to electric signals, and the incident light includes the modulated transmission light reflected by an object. The image signal processor generates depth information based on the electric signals. One of the unit pixels includes a non-silicon photodetector and at least one readout circuit. The non-silicon photodetector is formed at a silicon substrate, and the non-silicon photodetector includes at least one of non-silicon materials to generate a photocharge in response to the incident light. The at least one readout circuit is formed at the silicon substrate, the at least one readout circuit outputs a sensing signal based on the photocharge, where the sensing signal corresponds to one of the electric signals.

The pixel array may further include a plurality of color pixels formed at the silicon substrate between the unit pixels. The color pixels may convert visible light to color image signals. The visible light may be included in the incident light. The color pixels may have higher quantum efficiency with respect to the visible light than the unit pixels.

According to another aspect of an exemplary embodiment, a unit pixel of a three-dimensional image sensor includes: a non-silicon photodetector coupled to a first voltage through a conduction path, the non-silicon photodetector generating a photocharge in response to incident light; and at least one readout circuit coupled to the non-silicon photodetector through the conduction path, the at least one readout circuit includes a switching block, a readout block, and a first capacitor, and the at least one readout circuit configured to output a sensing signal for generating depth information on a distance to an object, based on the photocharge.

The non-silicon photodetector may be formed at a silicon substrate.

The non-silicon photodetector may be formed on a doped region in the at least one readout circuit.

The at least one readout circuit may be formed at a silicon substrate.

The non-silicon photodetector may be formed at a recess in a silicon substrate, the recess being adjacent to the at least one readout circuit.

The non-silicon photodetector may be formed on the at least one readout circuit.

A horizontal cross-section of the non-silicon photodetector may be decreased gradually along a depth of the horizontal cross-section such that an upper surface of the non-silicon photodetector may have a largest area and a bottom surface of the non-silicon photodetector have a smallest area.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a unit pixel of a three-dimensional image sensor according to example embodiments.

FIG. 2 is a block diagram illustrating an example of a readout block in the unit pixel of FIG. 1.

FIG. 3 is a circuit diagram illustrating an example of the unit pixel of FIG. 1.

FIG. 4 is a cross-sectional view of a unit pixel according to example embodiments.

FIGS. 5 and 6 are cross-sectional views illustrating examples of the unit pixel of FIG. 4.

FIG. 7 is a cross-sectional view of a unit pixel according to example embodiments.

FIGS. 8, 9 and 10 are cross-sectional views illustrating examples of the unit pixel of FIG. 7.

FIG. 11 is a block diagram illustrating a unit pixel of a three-dimensional image sensor according to example embodiments.

FIG. 12 is a circuit diagram illustrating an example of the unit pixel of FIG. 11.

FIG. 13 is a block diagram illustrating a unit pixel of a three-dimensional image sensor according to example embodiments.

FIG. 14 is a circuit diagram illustrating an example of the unit pixel of FIG. 13.

FIG. 15 is a cross-sectional view of a unit pixel according to example embodiments.

FIG. 16 is a diagram for describing quantum efficiency of non-silicon material.

FIG. 17 is a diagram for describing bandgap energy of germanium compound.

FIG. 18 is a block diagram illustrating a three-dimensional image sensor according to example embodiments.

FIG. 19 is a diagram for describing an example operation of the unit pixel of FIG. 13.

FIG. 20 illustrates a block diagram of an example embodiment of a computer system including a three-dimensional image sensor.

FIG. 21 illustrates a block diagram of an example embodiment of an interface employable in the computing system of FIG. 20.

### DETAILED DESCRIPTION OF THE EMBODIMENTS

Various example embodiments will be described more fully hereinafter with reference to the accompanying drawings, in which some example embodiments are shown. However, example embodiments may, be embodied in many different forms and should not be construed as limited to the example embodiments set forth herein. Rather, these example embodiments are provided so that this disclosure will be thorough and complete, and will fully convey the scope of the embodiments to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

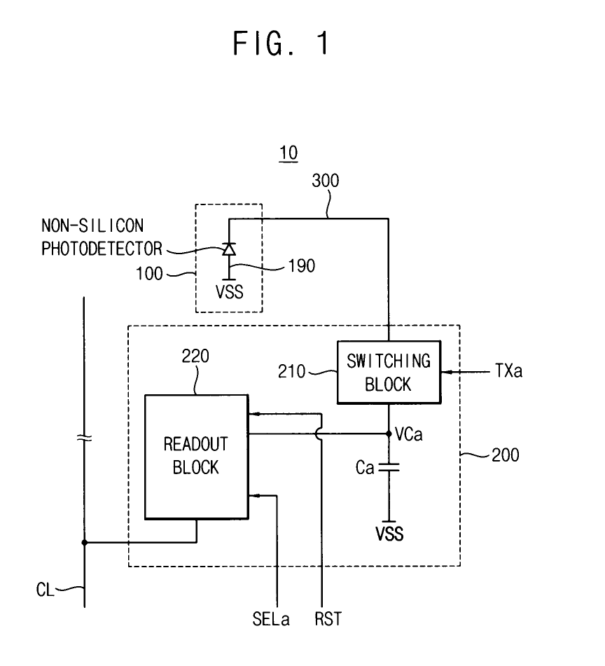

FIG. 1 is a block diagram illustrating a unit pixel of a three-dimensional image sensor according to example embodiments.

Referring to FIG. 1, a unit pixel 10 may include a non-silicon photodetector 100 and at least one readout circuit 200. FIG. 1 illustrates a non-limiting example such that the unit pixel 10 includes one readout circuit 200. However, the unit pixel 10 may include two or more readout circuits. For example, each unit pixel of the three-dimensional image sensor may include four readout circuits. In this case, the four readout circuits may generate four sensing signals, in response to four demodulation signals having phase difference of 90 degrees, respectively.

The non-silicon photodetector 100 may be formed at a silicon substrate and include at least one of non-silicon materials to generate photocharge in response to incident light. The non-silicon materials may be germanium, silicon germanium compound, indium gallium arsenide, amorphous silicon germanium compound, black silicon germanium compound, porous silicon germanium compound, germanium antimony telluride, indium gallium antimonide, indium arsenide, mercury cadmium telluride, silicide, transition metal silicide, selenide, telluride, sulfide, etc. For example, the non-silicon material may be silicon germanium compound Si₍₁₋ₓ₎Ge₍ₓ₎ that includes germanium and silicon of x:(1-x) ratio. For another example, the non-silicon material may be indium gallium arsenide In₍ₓ₎Ga₍₁₋ₓ₎As that includes indium and gallium of x:(1-x) ratio. The other compounds having various elements of various ratios may be used to form the non-silicon photodetector 100. Such non-silicon materials may have higher quantum efficiency, with respect to infrared light or light having a wavelength between 800 nm and 1400 nm than silicon materials.

In addition, the non-silicon materials may be silicon arsenic telluride SiAsTe, silicon antimony telluride SiSbTe, silicon antimony selenide SiAsSe, germanium phosphorus selenide GePSe, germanium arsenic selenide GeAsSe, germanium arsenic telluride GeAsTe, germanium arsenic sulfide GeAsS, germanium antimony telluride GeSbTe, germanium antimony selenide GeSbSe, germanium antimony sulfide GeSbS, germanium bismuth selenide GeBiSe, germanium bismuth telluride GeBiTe, tin bismuth telluride, SnBiTe, tin bismuth selenide SnBiSe, tin antimony selenide SnSbSe, tin antimony telluride, SnSbTe, tin arsenic telluride SnAsTe, tin arsenic selenide SnAsSe, tin phosphorus selenide SnPSe, tin phosphorus telluride SnPTe, lead phosphorus selenide PbPSe, lead arsenic selenide PbAsSe, lead arsenic telluride PbAsTe, lead antimony telluride PbSbTe, lead antimony selenide PbSbSe, lead antimony sulfide PbSbS, lead bismuth sulfide PbBiS, lead bismuth telluride PbBiTe, etc. In some example embodiments, the non-silicon photodetector 100 may be formed at the silicon substrate using photosensitive semiconductor quantum dots.

For example, the non-silicon photodetector 100 may include N-type non-silicon material at the P-type silicon substrate to form a PN diode. The non-silicon photodetector 100 may generate photocharge in response to incident light. The non-silicon photodetector may include a photo transistor, a photo gate, a pinned photo diode, etc.

The incident light may include infrared light or light having a wavelength between 800 nm and 1400 nm. The incident light may be modulated light that has periodically-varying intensity. The non-silicon photodetector 100 may provide the generated photocharge to the readout circuit 200 through a conduction path 300. The non-silicon photodetector 100 may be coupled to a low power voltage or a ground voltage VSS through a conduction path 190.

The readout circuit 200 may be formed at the silicon substrate. The readout circuit 200 may be configured to output a sensing signal based on the photocharge, where the sensing signal is used for generating depth information or distance information. According to example embodiments, the non-silicon photodetector 100 may be formed at a recess in the silicon substrate where the recess is adjacent to the readout circuit. The non-silicon photodetector 100 may also be formed on the readout circuit 200.

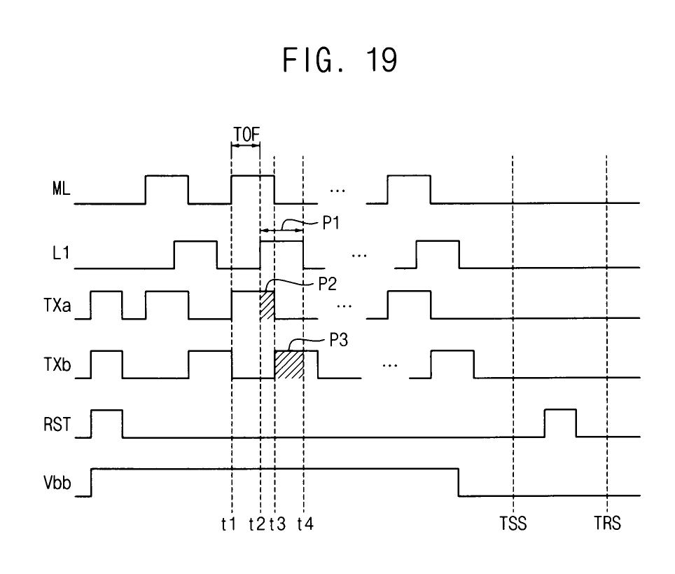

The readout circuit 200 may include a switching block 210, a readout block 220 and a capacitor Ca. The switching block 210 may provide the charge from the non-silicon photodetector 100 to the capacitor Ca in synchronization with a demodulation signal TXa. As described in FIG. 19, the demodulation signal TXa may have a voltage level changing with the time period of the incident light. For example, the demodulation signal TXa may have a frequency between 20 MHz and 60 MHz.

The capacitor Ca may collect the charge provided through the switching block 210. The capacitor Ca may include a first electrode, coupled to the low power voltage VSS, and a second electrode, coupled to the switching block 210 and the readout block 220. The readout block 220 may output the sensing signal to a column line CL in response to a selection signal SELa where the sensing signal corresponds to a voltage VCa of the capacitor Ca, i.e., a voltage at the second electrode of the capacitor Ca. The readout block 220 may reset the voltage VCa of the capacitor Ca in response to a reset signal RST.

The unit pixel 10 may operate in an integration mode, a readout mode and a reset mode. In the integration mode, the readout circuit 200 may collect the charge from the non-silicon photodetector 100 in the capacitor Ca in response to the demodulation signal TXa. After the integration mode, in the readout mode, the readout circuit 200 may amplify the voltage VCa of the capacitor Ca and output the amplified voltage to the column line CL in response to the selection signal SELa. In the reset mode, the readout circuit 200 may apply a reset voltage to the capacitor Ca in response to the reset signal RST. The reset voltage initializes the voltage VCa of the capacitor Ca. In some example embodiments, to perform correlated double sampling (CDS), the readout circuit 200 may amplify the initialized voltage VCa of the capacitor Ca and output the amplified voltage to the column line CL in response to the selection signal SELa. The demodulation signal TXa may be deactivated while the readout circuit 200 senses the voltage VCa of the capacitor Ca.

In general, devices of sensing a depth, i.e., a distance to an object, may include a stereo image sensor, a time-of-flight (TOF) depth sensor, etc. The TOF depth sensor is in the three-dimension image sensor to obtain depth information, in addition to color image information. The three-dimensional TOF image sensor measures the distance to the object using infrared light or near-infrared light. The three-dimensional TOF image sensor using a silicon photodetector has relatively low quantum efficiency due to the low absorption coefficient of silicon with respect to the infrared light. The silicon material has the quantum efficiency of about 10% with respect to the infrared light. The silicon material has the quantum efficiency of about 60% with respect to the visible light. Accordingly, the unit pixel or the depth pixel, for measuring the depth information, has relatively large occupation area to secure sufficient signal-to-noise ratio (SNR). Such increase of the occupation area of the unit pixel causes degradation of resolution and increase of the size and cost of the three-dimensional image sensor.

The unit pixel 10 of the three-dimensional image sensor, according to example embodiments, includes the non-silicon photodetector 100 having the quantum efficiency with respect to the infrared light than the silicon photodetector. Thus, the unit pixel 10 may provide enhanced quality of image with the reduced occupation area and may increase the resolution of the three-dimensional image sensor.

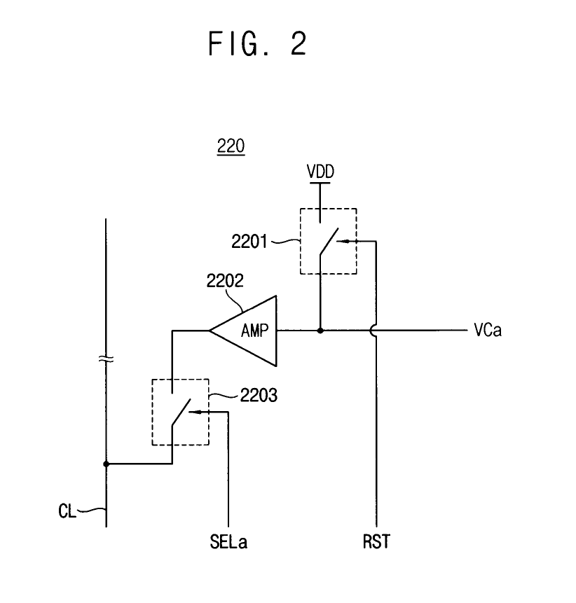

FIG. 2 is a block diagram illustrating an example of a readout block in the unit pixel of FIG. 1.

Referring to FIG. 2, a readout block 220 may include a first switch 2201, an amplifier 2202 and a second switch 2203. The first switch 2201 may apply a reset voltage VDD to a capacitor Ca in response to a reset signal RST. The reset voltage initializes a voltage VCa of the capacitor Ca. For example, the first switch 2201 may charge the capacitor CA periodically in response to the reset signal RST to perform correlated double sampling (CDS).

The amplifier 2202 may amplify the voltage VCa of the capacitor Ca and output the amplified voltage. For example, the amplifier 2202 may be implemented with one transistor that operates in an active mode or in a linear operation mode. The amplifier 2202 may operate as a source follower buffer transistor to amplify the voltage VCa of the capacitor Ca. The second switch 2203 may transfer the output of the amplifier 2202 to a column line CL in response to a selection signal SELa. For example, the first and second switches 2201 and 2203 may include transistors.

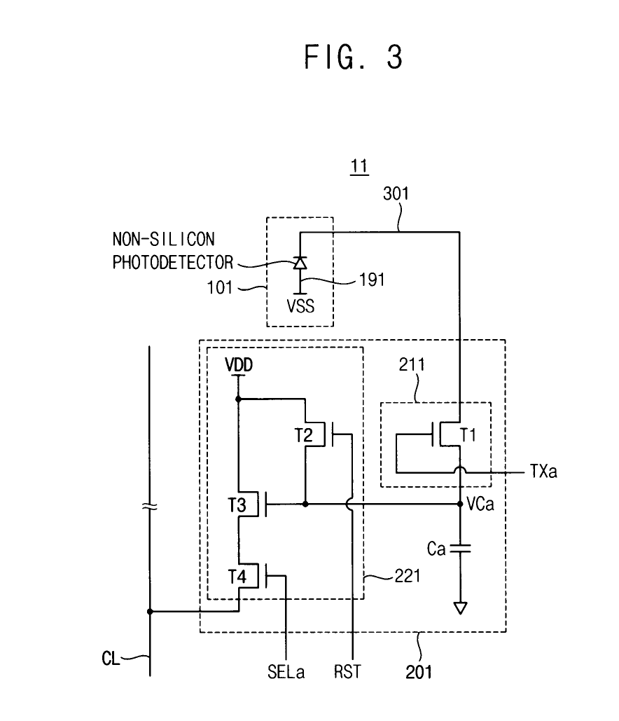

FIG. 3 is a circuit diagram illustrating an example of the unit pixel of FIG. 1.

Referring to FIG. 3, a unit pixel 11 may include a non-silicon photodetector 101 and at least one readout circuit 201. As described above, the non-silicon photodetector 101 may be formed at a silicon substrate and include at least one of non-silicon materials to generate photocharge in response to incident light. The non-silicon photodetector 101 may provide the photocharge to the readout circuit 201 through a conduction path 301. The non-silicon photodetector 101 may be coupled to a low power voltage or a ground voltage VSS through a conduction path 191.

The readout circuit 201 may include a switching block 211, a readout block 221 and a capacitor Ca. The switching block 211 may include a first transistor T1 that is coupled between the capacitor Ca and the non-silicon photodetector 101. The first transistor T1 may receive a demodulation signal TXa through a control electrode, i.e., a gate electrode, and provide the charge from the non-silicon photodetector 101 to the capacitor Ca in synchronization with the demodulation signal TXa. The demodulation signal TXa may have a voltage level changing with the time period of the incident light.

The capacitor Ca may collect the charge provided through the switching block 211. The capacitor Ca may include a first electrode coupled to the low power voltage VSS and a second electrode coupled to the switching block 211 and the readout block 221.

The readout block 221 may include a second transistor T2, a third transistor T3, and a fourth transistor T4. The second transistor T2 may be coupled between the second electrode of the capacitor Ca and a reset voltage. For example, the reset voltage may be a high power voltage VDD. The second transistor T2 may apply the high power voltage VDD to the second electrode of the capacitor Ca in response to a reset signal RST. The second transistor T2 may initialize the voltage VCa of the capacitor Ca to the high power voltage VDD in response to the reset signal RST. The third transistor T3 may be coupled between the high power voltage VDD and the fourth transistor T4, and the fourth transistor T4 may be coupled between the third transistor T3 and a column line CL. The third transistor T3 may receive the voltage VCa of the capacitor Ca through a control electrode and output a current to the fourth transistor T4 in response to the voltage VCa of the capacitor Ca. The fourth transistor T4 may output a sensing signal to the column line CL in response to a selection signal SELa. As such, the readout block 221 may output the sensing signal corresponding to the voltage VCa of the capacitor Ca to the column line CL in response to the selection signal SELa.

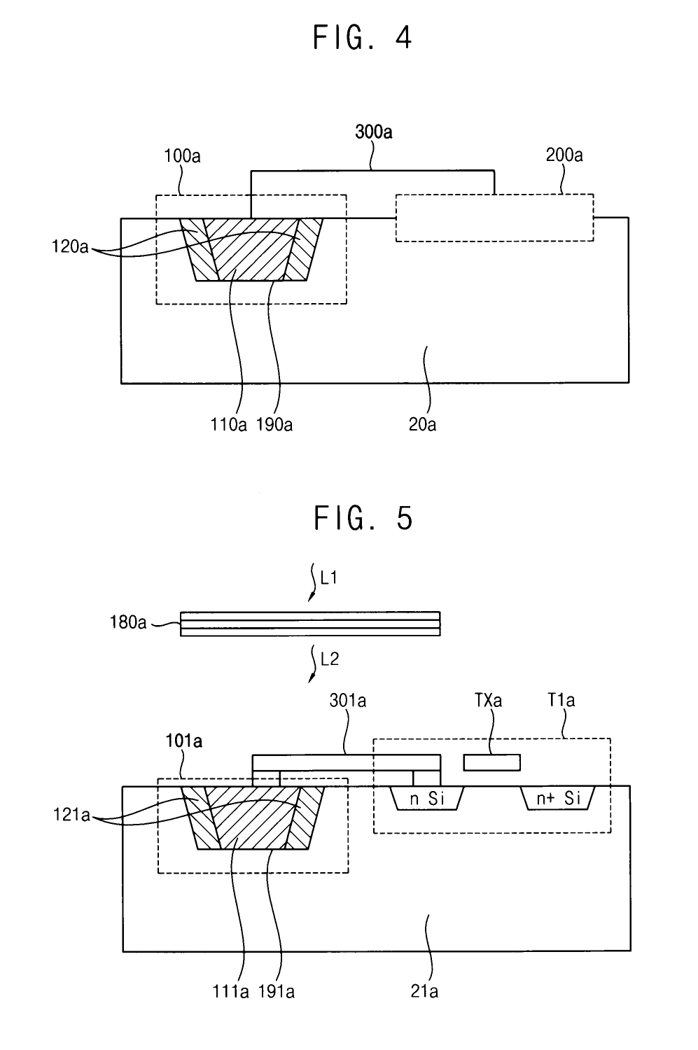

FIG. 4 is a cross-sectional view of a unit pixel according to example embodiments.

As illustrated in FIG. 4, the unit pixel 10 of FIG. 1 may be formed at the silicon substrate 20a. The non-silicon photodetector 100 of FIG. 1 may be formed in a non-silicon photodetector region 100a and the readout circuit 200 of FIG. 1 may be formed in a readout circuit region 200a. The non-silicon photodetector region 100a and the readout circuit region 200a may be electrically connected through a conduction path 300a.

As illustrated in FIG. 4, the readout circuit region 200a may be formed near an upper surface of the silicon substrate 20a and the non-silicon photodetector region 100a may be formed at a recess in the silicon substrate 20a where the recess is adjacent to the readout circuit region 200a. The non-silicon photodetector region 100a may include an insulation portion 120a and a non-silicon material portion 110a surrounded by the insulation portion 120a. For example, the non-silicon material portion 110a may be formed through a growth process or a deposition process to fill the recess with the above-mentioned non-silicon material. The bottom surface 190a of the non-silicon material portion 110a may contact the silicon substrate 20a so that the non-silicon material portions of a plurality of unit pixels may be commonly connected with the silicon substrate 20a.

As illustrated in FIG. 4, a horizontal cross-section of the non-silicon photodetector or the non-silicon material portion 110a may be decreased gradually along a depth of the horizontal cross-section. In other words, the insulation portion 120a may be formed like a truncated funnel and the non-silicon material may fill the inner space of the funnel-like insulation portion 120a. As a result, an upper surface of the non-silicon photodetector may have a largest area and a bottom surface of the non-silicon photodetector may have a smallest area.

The silicon substrate 20a may include a P-type epitaxial substrate that is formed on a P-type bulk silicon substrate through an epitaxial process. For example, the P-type epitaxial substrate may be formed using a silicon source gas to have the same crystalline structure with the P-type bulk silicon substrate. The silicon source gas may include at least one of silane, dichlorosilane (DCS), trichlorosilane (TCS) and hexachlorosilane (DCS).

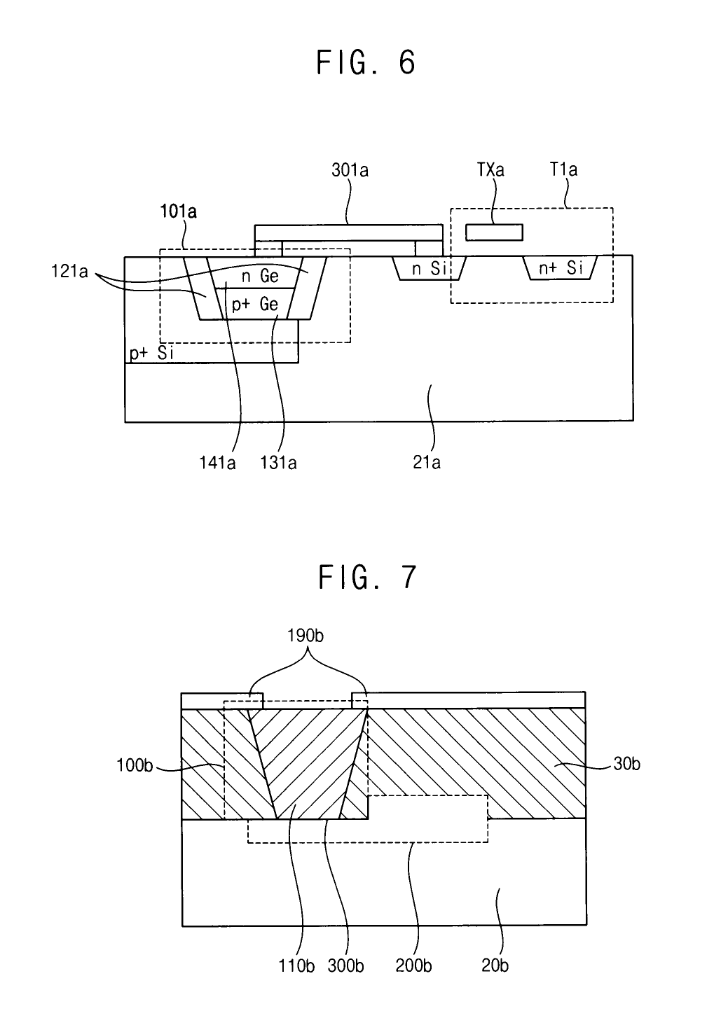

FIGS. 5 and 6 are cross-sectional views illustrating examples of the unit pixel of FIG. 4.

Referring to FIG. 5, the unit pixel 10 of FIG. 1 may be formed at the silicon substrate 21a. The non-silicon photodetector 100 of FIG. 1 may be formed in a non-silicon photodetector region 101a and the readout circuit 200 of FIG. 1 may be formed adjacent to the photodetector region 101a. For convenience, only one transistor region T1a included in the readout circuit region is illustrated. For example, the first transistor T1 in FIG. 3 may be formed in the transistor region T1a. The non-silicon photodetector region 101a and the first transistor T1 may be electrically connected through a conduction path 301a. The conduction path 301a may include a wire, in a metal layer over the silicon substrate 21a, and vertical contacts, connecting the wire and the upper surface of the silicon substrate 21a.

The transistor region T1a may be formed near the upper surface of the silicon substrate 21a. The transistor region T1a may include N-type silicon regions and a gate electrode TXa. The non-silicon photodetector region 101a may be formed at a recess in the silicon substrate 21a. The recess is adjacent to the readout circuit region. The readout circuit region includes the transistor region T1a. The non-silicon photodetector region 101a may include an insulation portion 121a and a non-silicon material portion 111a surrounded by the insulation portion 121a. The bottom surface 191a of the non-silicon material portion 111a may contact with the silicon substrate 21a so that the non-silicon material portions of a plurality of unit pixels may be commonly connected with the silicon substrate 21a.

A filter 180a may be formed over the non-silicon photodetector region 101a. The filter 180a may pass light L2 having a wavelength of a predetermined range among the incident light L1. For example, the filter 180a may be a band pass filter that passes infrared light having the wavelength between 800 nm and 1400 nm or a band pass filter that passes near-infrared light having the wavelength between 800 nm and 900 nm.

Referring to FIG. 6, the non-silicon material portion 111a of FIG. 5 may include P-type germanium 131a and N-type germanium 141a. The P-type germanium 131a may be formed on the P-type silicon and the N-type germanium 141a may be formed on the P-type germanium 131a. In other words, the P-type germanium 131a and the N-type germanium 141a may form a PN junction. Thus, the non-silicon photodetector 100 of FIG. 1 may form a PN junction diode. In other example embodiments, the non-silicon material portion 111a may include intrinsic germanium. Thus, the non-silicon photodetector 100 may be a photoconductor including the intrinsic germanium. In still other example embodiments, the non-silicon material portion 111a may include intrinsic germanium and P-type germanium formed on a doped region including N-type silicon. Thus, the doped region and the non-silicon photodetector 100 may form a PIN junction diode.

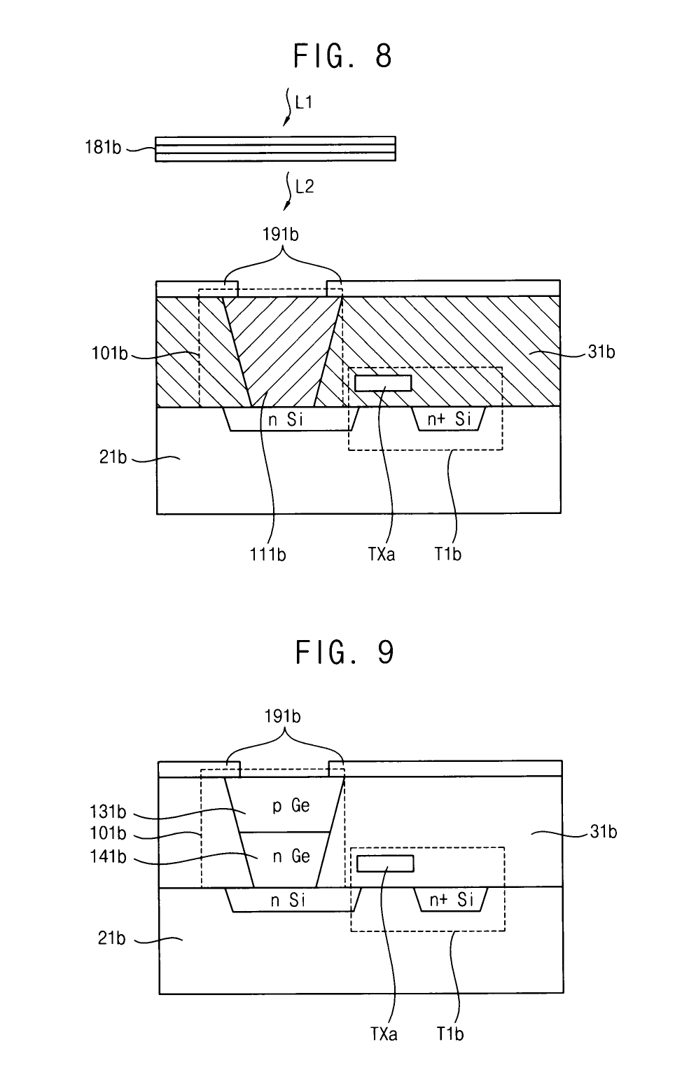

FIG. 7 is a cross-sectional view of a unit pixel according to example embodiments.

The unit pixel 10 of FIG. 1 may be formed at the silicon substrate 20b as illustrated in FIG. 7. The non-silicon photodetector 100 of FIG. 1 may be formed in a non-silicon photodetector region 100b and the readout circuit 200 of FIG. 1 may be formed in a readout circuit region 200b. The non-silicon photodetector region 100b and the readout circuit region 200b may be electrically connected through a conduction path 300b.

As illustrated in FIG. 7, the readout circuit region 200b may be formed near an upper surface of the silicon substrate 20b and the non-silicon photodetector region 100b may be formed on the readout circuit region 200b. The non-silicon photodetector region 100b may include a non-silicon material portion 110b formed in an insulation material layer 30b. The non-silicon photodetector region 100b may be electrically connected to the non-silicon photodetector regions of the neighboring unit pixels through conduction paths 190b. For example, a planarization process may be performed on the non-silicon material portion 110b and the insulation material layer 30b before forming the conduction paths 190b.

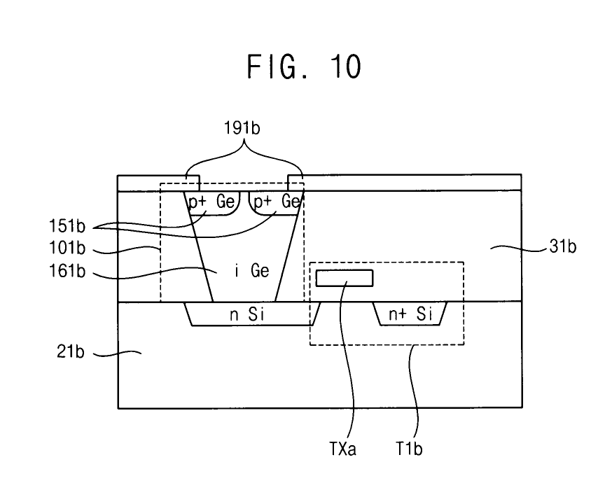

FIGS. 8, 9 and 10 are cross-sectional views illustrating examples of the unit pixel of FIG. 7.

Referring to FIG. 8, the unit pixel 10 of FIG. 1 may be formed at the silicon substrate 21b. The non-silicon photodetector 100 of FIG. 1 may be formed in a non-silicon photodetector region 101b and the readout circuit 200 of FIG. 1 may be formed under the photodetector region 101b. For convenience, only one transistor region T1b in the readout circuit region is illustrated. For example, the first transistor T1 in FIG. 3 may be formed in the transistor region T1b. The non-silicon photodetector region 101b may include a non-silicon material region 111b formed in an insulation material layer 30b. The non-silicon material region 111b formed in an insulation material layer 31b. The first transistor T1 may be electrically connected to the non-silicon material region 111b through a bottom surface of the non-silicon material region 111b.

The transistor region T1b may be formed near the upper surface of the silicon substrate 21b. The transistor region T1b may include N-type silicon regions and a gate electrode TXa. The non-silicon material region 111b may be formed on a doped region including N-type silicon. The bottom surface of the non-silicon material portion 111b may contact with the doped region forming the transistor T1.

A filter 181b may be formed over the non-silicon photodetector region 101b. The filter 181b may pass light L2 having a wavelength of a predetermined range among the incident light L1. For example, the filter 181b may be a band pass filter that passes infrared light having the wavelength between 800 nm and 1400 nm or a band pass filter that passes near-infrared light having the wavelength between 800 nm and 900 nm.

Referring to FIG. 9, the non-silicon material portion 111b of FIG. 8 may include P-type germanium 131b and N-type germanium 141b. The N-type germanium 141b may be formed on the doped region including N-type silicon and the P-type germanium 131b may be formed on the N-type germanium 141b. In other words, the P-type germanium 131b and the N-type germanium 141b may form a PN junction. Thus, the non-silicon photodetector 100 of FIG. 1 may form a PN junction diode.

Referring to FIG. 10, the non-silicon material portion 111b of FIG. 8 may include intrinsic germanium 161b and P-type germanium 151b. The intrinsic germanium 161b may be formed on the doped region including N-type silicon and the P-type germanium 151b may be formed in the upper portions of the intrinsic germanium 161b. In other words, the P-type germanium 151b, the intrinsic germanium 161b, and the doped region may form a PIN junction. Thus, the doped region and the non-silicon photodetector 100 of FIG. 1 may form a PIN junction diode. In some example embodiments, the P-type germanium 151b may be omitted in the non-silicon photodetector region 101b of FIG. 10. In this case, the non-silicon photodetector 100 of FIG. 1 may be a photoconductor including intrinsic germanium 161b.

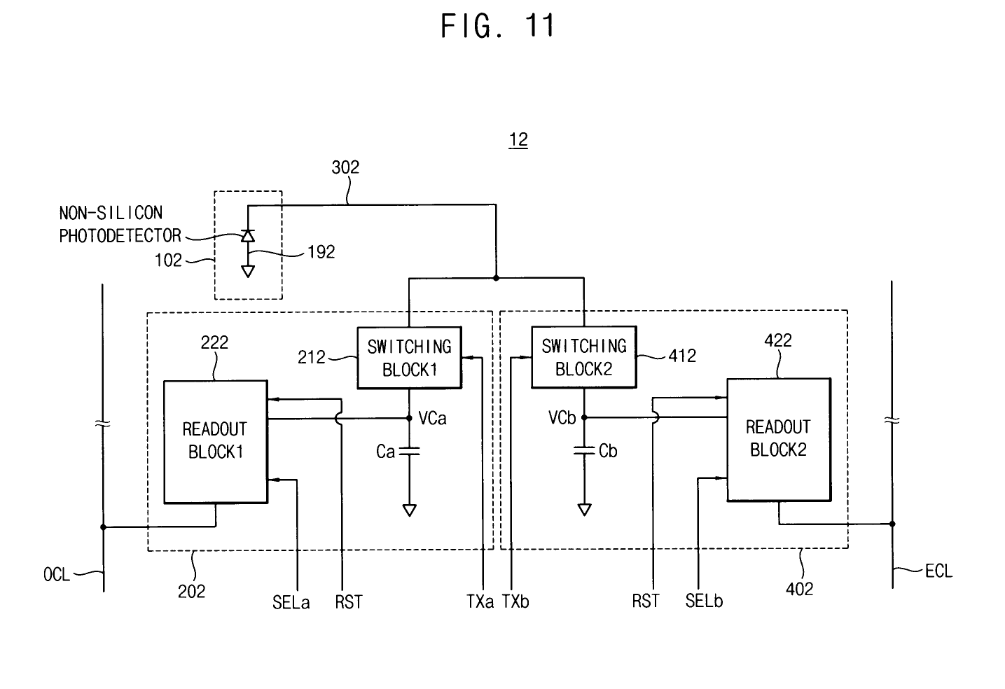

FIG. 11 is a block diagram illustrating a unit pixel of a three-dimensional image sensor according to example embodiments.

Referring to FIG. 11, a unit pixel 12 may include a non-silicon photodetector 102, a first readout circuit 202 and a second readout circuit 402. FIG. 11 illustrates a non-limiting example that the unit pixel 12 includes the two readout circuits 202 and 402, but the unit pixel 12 may include three or more readout circuits. The readout circuits 202 and 402 may be electrically connected to the non-silicon photodetector 102 through a conduction path 302.

The non-silicon photodetector 102 may be formed at a silicon substrate and include at least one of non-silicon materials to generate photocharge in response to incident light. The non-silicon materials may be germanium, silicon germanium compound, indium gallium arsenide, amorphous silicon germanium compound, black silicon germanium compound, porous silicon germanium compound, germanium antimony telluride, indium gallium antimonide, indium arsenide, mercury cadmium telluride, silicide, transition metal silicide, selenide, telluride, sulfide, etc. For example, the non-silicon material may be silicon germanium compound Si₍₁₋ₓ₎Ge₍ₓ₎ that includes germanium and silicon of x:(1-x) ratio. For another example, the non-silicon material may be indium gallium arsenide In₍ₓ₎Ga₍₁₋ₓ₎. As that includes indium and gallium of x:(1-x) ratio. The other compounds having various elements of various ratios may be used to form the non-silicon photodetector 102. Such non-silicon materials may have higher quantum efficiency, with respect to infrared light or light having a wavelength between 800 nm and 1400 nm than silicon materials.

In addition, the non-silicon materials may be silicon arsenic telluride SiAsTe, silicon antimony telluride SiSbTe, silicon antimony selenide SiAsSe, germanium phosphorus selenide GePSe, germanium arsenic selenide GeAsSe, germanium arsenic telluride GeAsTe, germanium arsenic sulfide GeAsS, germanium antimony telluride GeSbTe, germanium antimony selenide GeSbSe, germanium antimony sulfide GeSbS, germanium bismuth selenide GeBiSe, germanium bismuth telluride GeBiTe, tin bismuth telluride, SnBiTe, tin bismuth selenide SnBiSe, tin antimony selenide SnSbSe, tin antimony telluride, SnSbTe, tin arsenic telluride SnAsTe, tin arsenic selenide SnAsSe, tin phosphorus selenide SnPSe, tin phosphorus telluride SnPTe, lead phosphorus selenide PbPSe, lead arsenic selenide PbAsSe, lead arsenic telluride PbAsTe, lead antimony telluride PbSbTe, lead antimony selenide PbSbSe, lead antimony sulfide PbSbS, lead bismuth sulfide PbBiS, lead bismuth telluride PbBiTe, etc. In some example embodiments, the non-silicon photodetector 102 may be formed at the silicon substrate using photosensitive semiconductor quantum dots.

The non-silicon photodetector 102 may generate a photocharge in response to incident light. The incident light may be infrared light or light having a wavelength between 800 nm and 1400 nm. The incident light may be modulated light that has periodically-varying intensity. The non-silicon photodetector 102 may provide the generated photocharge to the readout circuits 202 and 204 through the conduction path 302. The non-silicon photodetector 102 may be coupled to a low power voltage or a ground voltage VSS through a conduction path 192.

The first and second readout circuits 202 and 402 may be formed at the silicon substrate and the first and second readout circuits 202 and 402 may be configured to output respective sensing signals based on the photocharge generated in the non-silicon photodetector 102. The sensing signals are used for generating depth information or distance information. According to example embodiments, the non-silicon photodetector 102 may be formed at a recess in the silicon substrate where the recess is adjacent to the readout circuits 202 and 402. The non-silicon photodetector 102 may also be formed on the readout circuits 202 and 402.

The first readout circuit 202 may include a first switching block 212, a first readout block 222, and a first capacitor Ca. The first switching block 212 may provide the charge from the non-silicon photodetector 102 to the first capacitor Ca in synchronization with a first demodulation signal TXa. The first demodulation signal TXa may have a voltage level changing with the time period of the incident light. For example, the first demodulation signal TXa may have a frequency between 20 MHz and 60 MHz. The first capacitor Ca may collect the charge provided through the first switching block 212 in response to the first demodulation signal TXa. The first capacitor Ca may include a first electrode coupled to the low power voltage VSS and a second electrode coupled to the first switching block 212 and the first readout block 222. The first readout block 222 may output a first sensing signal to a first column line OCL in response to a first selection signal SELa. The first sensing signal corresponds to a voltage VCa of the first capacitor Ca, i.e., a voltage at the second electrode of the first capacitor Ca. The first column line OCL may be an odd-numbered line of a plurality of column lines of a pixel array. The first readout block 222 may initialize the voltage VCa of the first capacitor Ca in response to a reset signal RST.

The second readout circuit 402 may include a second switching block 412, a second readout block 422, and a second capacitor Cb. The second switching block 412 may provide the charge from the non-silicon photodetector 102 to the second capacitor Cb in synchronization with a second demodulation signal TXb. The second demodulation signal TXb may have a voltage level changing with the time period of the incident light but a different phase from the first demodulation signal TXa. For example, the second demodulation signal TXb may have a frequency between 20 MHz and 60 MHz. For example, the phase difference between the first and second demodulation signals TXa and TXb may be 180 degrees. The second capacitor Cb may collect the charge provided through the second switching block 412 in response to the second demodulation signal TXb. The second capacitor Cb may include a first electrode coupled to the low power voltage VSS and a second electrode coupled to the second switching block 412 and the second readout block 422. The second readout block 422 may output a second sensing signal to a second column line ECL in response to a second selection signal SELb. The second sensing signal corresponds to a voltage VCb of the second capacitor Cb, i.e., a voltage at the second electrode of the second capacitor Cb. The second column line ECL may be an even-numbered line of the column lines of the pixel array. The second readout block 422 may initialize the voltage VCb of the second capacitor Cb in response to the reset signal RST.

The unit pixel 12 may operate in an integration mode, a readout mode, and a reset mode. In the integration mode, the first readout circuit 202 may collect the charge from the non-silicon photodetector 102 in the first capacitor CA in response to the first demodulation signal TXa and the second readout circuit 402 may collect the charge from the non-silicon photodetector 102 in the second capacitor Cb in response to the second demodulation signal TXb. After the integration mode, in the readout mode, the first readout circuit 202 may amplify the voltage VCa of the first capacitor Ca and output the amplified voltage to the first column line OCL in response to the first selection signal SELa. The second readout circuit 402 may amplify the voltage VCb of the second capacitor Cb and output the amplified voltage to the second column line ECL in response to the second selection signal SELb. In the reset mode, the first and second readout circuit 202 and 402 may apply a reset voltage to the first and second capacitors Ca and Cb in response to the reset signal RST. The reset voltage initializes the voltages VCa and VCb of the first and second capacitors Ca and Cb. In some example embodiments, to perform correlated double sampling (CDS), the first and second readout circuits 202 and 402 may amplify the initialized voltages VCa and VCb of the first and second capacitors Ca and Cb and output the amplified voltages to the first and second column lines OCL and ECL in response to the first and second selection signals SELa and SELb, respectively. The first and second demodulation signals TXa and TXb may be deactivated while the first and second readout circuits 202 and 402 sense the voltages VCa and VCb of the first and second capacitors Ca and Cb.

As illustrated in FIG. 19, the first demodulation signal TXa and the second demodulation signal TXb may have a phase difference of 180 degrees. In other words, the first and second demodulation signals TXa and TXb may have complementary signal levels. For example, the second demodulation signals TXb may be an inversion signal of the first demodulation signal TXa. In this case, the photocharge generated in the non-silicon photodetector 102 may be alternatively provided to the first and second capacitors Ca and Cb per half cyclic period of the demodulation signals TXa and TXb.

The unit pixel 12 of the three-dimensional image sensor, according to example embodiments, includes the non-silicon photodetector 102 having the quantum efficiency with respect to the infrared light, rather than the silicon photodetector. Thus, the unit pixel 12 may provide enhanced quality of image with the reduced occupation area and may increase the resolution of the three-dimensional image sensor.

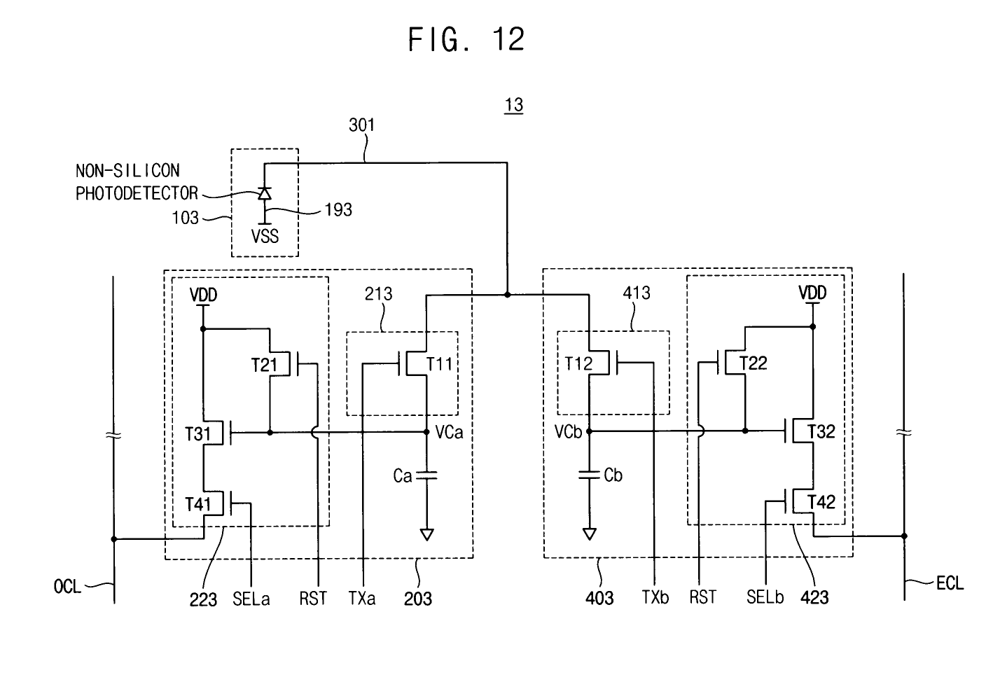

FIG. 12 is a circuit diagram illustrating an example of the unit pixel of FIG. 11.

Referring to FIG. 12, a unit pixel 13 may include a non-silicon photodetector 103, a first readout circuit 203, and a second readout circuit 403. The first readout circuit 203 may include a first switching block 213, a first readout block 223, and a first capacitor Ca. The second readout circuit 403 may include a second switching block 413, a second readout block 423, and a second capacitor Cb.

The first switching block 213 may include a first transistor T11 that is coupled between the first capacitor Ca and the non-silicon photodetector 103. The first transistor T11 may receive a first demodulation signal TXa through a control electrode, i.e., a gate electrode, and provides the charge from the non-silicon photodetector 103 to the first capacitor Ca in synchronization with the first demodulation signal TXa. The first demodulation signal TXa may have a voltage level changing with the time period of the incident light.

The first capacitor Ca may collect the charge provided through the first switching block 213. The first capacitor Ca may include a first electrode, coupled to the low power voltage VSS, and a second electrode, coupled to the first switching block 213 and the first readout block 223.

The first readout block 223 may include a second transistor T21, a third transistor T31, and a fourth transistor T41. The second transistor T21 may be coupled between the second electrode of the first capacitor Ca and a reset voltage. For example, the reset voltage may be a high power voltage VDD. The second transistor T21 may apply the high power voltage VDD to the second electrode of the first capacitor Ca in response to a reset signal RST. The second transistor T21 may initialize the voltage VCa of the first capacitor Ca to the high power voltage VDD in response to the reset signal RST. The third transistor T31 may be coupled between the high power voltage VDD and the fourth transistor T41. The fourth transistor T41 may be coupled between the third transistor T31 and a first column line OCL. The third transistor T31 may receive the voltage VCa of the first capacitor Ca through a control electrode and output a current to the fourth transistor T41 in response to the voltage VCa of the first capacitor Ca. The fourth transistor T41 may output a first sensing signal to the first column line OCL in response to a first selection signal SELa. Therefore, the first readout block 223 may output the first sensing signal corresponding to the voltage VCa of the first capacitor Ca to the first column line OCL in response to the first selection signal SELa.

The configuration and operation of the second readout circuit 403 is similar to the first readout circuit 203. Repeated descriptions are omitted. The second switching block 413 provides the charge from the non-silicon photodetector 103 to the second capacitor Cb in synchronization with the second demodulation signal TXb, instead of the first demodulation signal TXa.

As illustrated in FIG. 19, the first demodulation signal TXa and the second demodulation signal TXb may have a phase difference of 180 degrees as illustrated in FIG. 19. For example, the second demodulation signals TXb may be an inversion signal of the first demodulation signal TXa. In this case, the photocharge generated in the non-silicon photodetector 102 may be alternatively provided to the first and second capacitors Ca and Cb per half cyclic period of the demodulation signals TXa and TXb. The photocharge, corresponding to one half of the cyclic period, may be collected in the first capacitor Ca and the photocharge, corresponding to the other half of the cyclic period, may be collected in the second capacitor Cb.

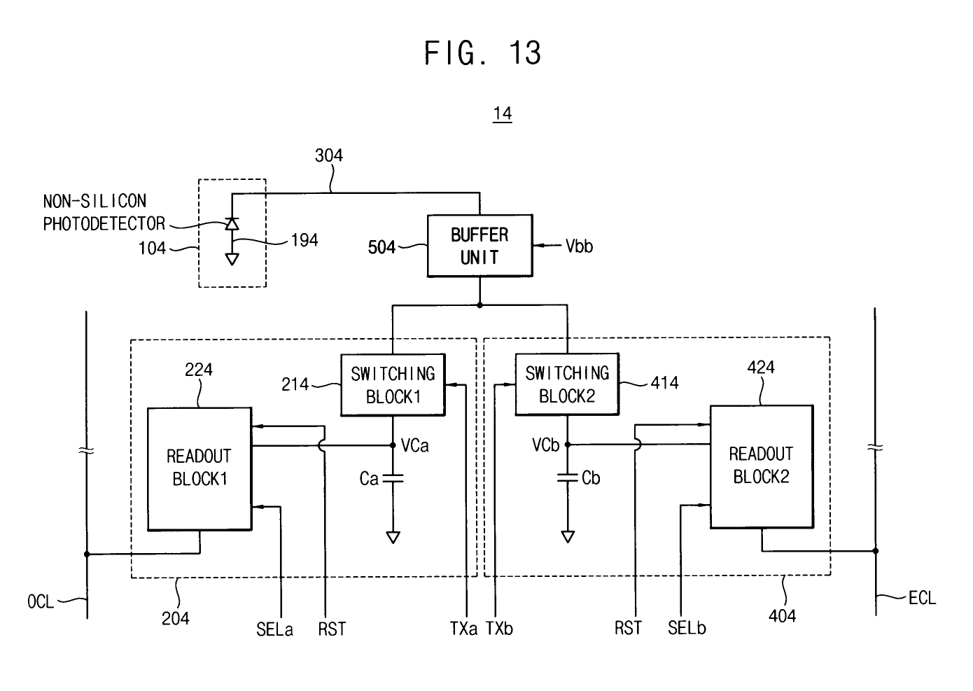

FIG. 13 is a block diagram illustrating a unit pixel of a three-dimensional image sensor according to example embodiments.

Referring to FIG. 13, a unit pixel 14 may include a non-silicon photodetector 104, a first readout circuit 204, a second readout circuit 404, and a buffer unit 504. The readout circuits 204 and 404 may be electrically connected to the non-silicon photodetector 104 through a conduction path 304 and the buffer unit 504. The configuration and operation of the unit pixel 14 of FIG. 13 are similar to those of the unit pixels 12 and 13 of FIGS. 11 and 12 except the buffer unit 504. Repeated descriptions may be omitted.

The buffer unit 504 may be coupled between the non-silicon photodetector 104 and the readout circuits 204 and 404. The buffer unit 504 may be turned on and off in response to a buffer control signal Vbb. The buffer unit 504 may transfer the charge from the non-silicon photodetector 104 to the readout circuits 204 and 404 in response to the buffer control signal Vbb. The buffer unit 504 may maintain a substantially constant bias across the non-silicon photodetector 104. The charge transfer between the non-silicon photodetector 504 and the readout circuits 204 and 404 may be buffered by the buffer unit 504 so that the non-silicon photodetector 104 may be isolated from capacitive interference due to the switching operations of the switching blocks 214 and 414.

The unit pixel 14 may operate in an integration mode, a readout mode, and a reset mode. The buffer control signal Vbb may be activated in the integration mode to turn on the buffer unit 504. In the integration mode, the first readout circuit 204 may collect the charge from the non-silicon photodetector 104 in the first capacitor CA in response to the first demodulation signal TXa, and the second readout circuit 404 may collect the charge from the non-silicon photodetector 104 in the second capacitor Cb in response to the second demodulation signal TXb. After the integration mode, in the readout mode, the first readout circuit 204 may amplify the voltage VCa of the first capacitor Ca and output the amplified voltage, i.e., the first sensing signal to the first column line OCL in response to the first selection signal SELa, and the second readout circuit 404 may amplify the voltage VCb of the second capacitor Cb and output the amplified voltage, i.e., the second sensing signal to the second column line ECL in response to the second selection signal SELb. In the reset mode, the first and second readout circuit 204 and 404 may apply a reset voltage to the first and second capacitors Ca and Cb in response to the reset signal RST to initialize the voltages VCa and VCb of the first and second capacitors Ca and Cb. In some example embodiments, to perform correlated double sampling (CDS), the first and second readout circuits 202 and 402 may amplify the initialize voltages VCa and VCb of the first and second capacitors Ca and Cb and output the amplified voltages to the first and second column lines OCL and ECL in response to the first and second selection signals SELa and SELb, respectively. The first and second demodulation signals TXa and TXb may be deactivated while the first and second readout circuits 204 and 404 sense the voltages VCa and VCb of the first and second capacitors Ca and Cb.

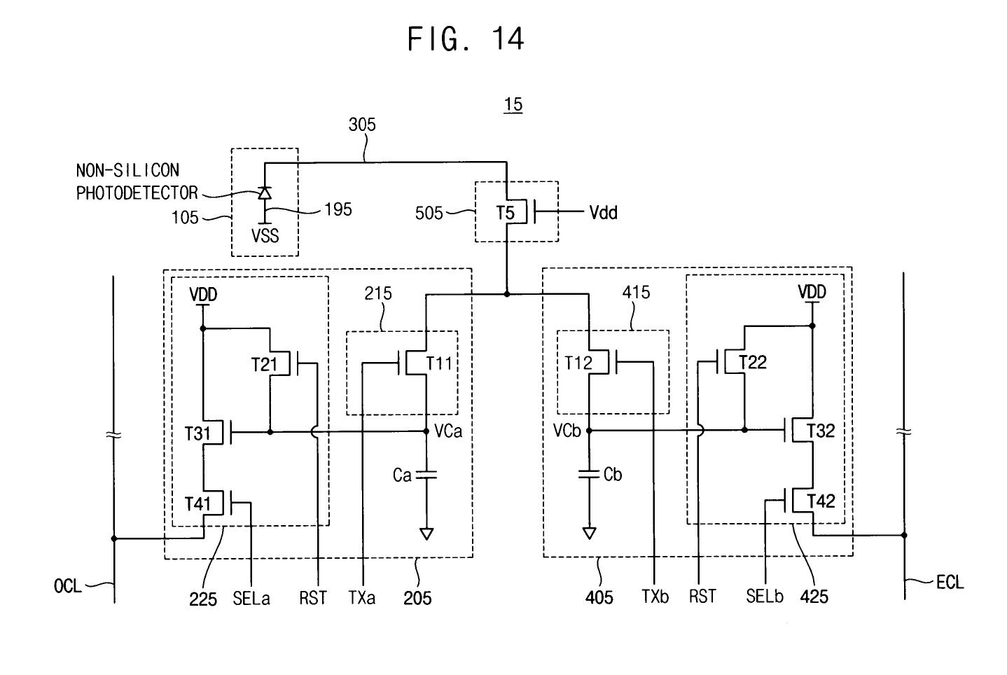

FIG. 14 is a circuit diagram illustrating an example of the unit pixel of FIG. 13.

Referring FIG. 14, a unit pixel 15 may include a non-silicon photodetector 105, a first readout circuit 205, a second readout circuit 405, and a buffer unit 505. The configuration and operation of the unit pixel 15 of FIG. 14 are similar to those of the unit pixels 12, 13 and 14 of FIGS. 11, 12 and 13. Repeated descriptions may be omitted. The buffer unit 505 may include a buffer transistor T5. The buffer transistor T5 may receive the buffer control signal Vbb through a control electrode, i.e., a gate electrode, and control the electrical connection between the non-silicon photodetector 105 and the readout circuits 205 and 405 in response to the buffer control signal Vbb. The buffer transistor T5 of the buffer unit 505 may maintain substantially constant bias across the non-silicon photodetector 505. The charge transfer between the non-silicon photodetector 505 and the readout circuits 205 and 405 may be buffered by the buffer transistor T5 so that the non-silicon photodetector 105 may be isolated from capacitive interference due to the switching operations of the switching blocks 215 and 415. The output capacitance of the non-silicon photodetector 105 may be kept small through merging the buffer transistor T5 between the non-silicon photodetector 105 and the readout circuits 205 and 405.

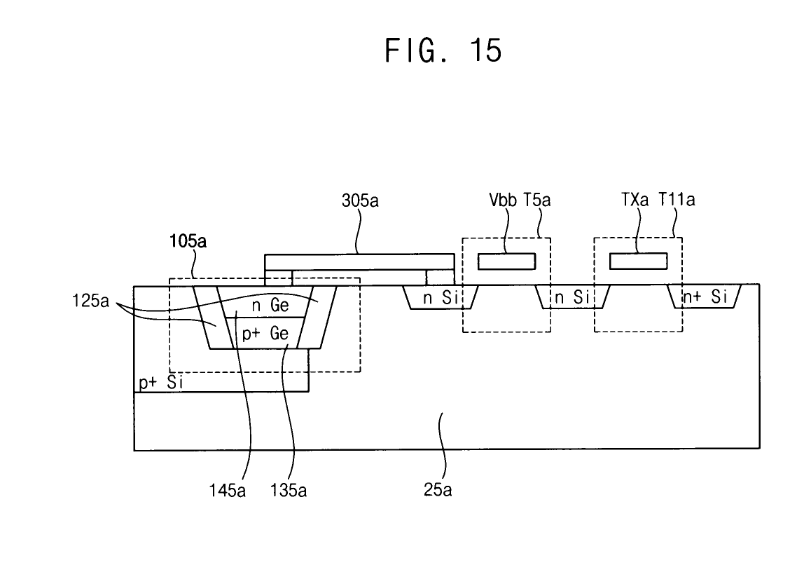

FIG. 15 is a cross-sectional view of a unit pixel according to example embodiments.

Referring to FIG. 15, the unit pixel 15 of FIG. 14 may be formed at the silicon substrate 25a. The non-silicon photodetector 105 of FIG. 14 may be formed in a non-silicon photodetector region 105a and the readout circuits 205 and 405 of FIG. 14 may be formed adjacent to the photodetector region 105a. For convenience, only two transistor regions T5a and T11a are illustrated in FIG. 15. For example, the buffer transistor T5 of the buffer unit 505 in FIG. 14 may be formed in the buffer transistor region T5a and the switching transistor T11 of the first switching block 215 may be formed in the switching transistor region T11a. The non-silicon photodetector region 105a and the buffer transistor T5 may be electrically connected through a conduction path 305a. The conduction path 305a may include a wire in a metal layer over the silicon substrate 25a and vertical contacts connecting the wire and the upper surface of the silicon substrate 25a.

The buffer transistor region T5a and the switching transistor region T11a may be formed near the upper surface of the silicon substrate 25a.

The buffer transistor region T5a may include N-type silicon regions and a gate electrode Vbb. The switching transistor region T11a may include N-type silicon regions and a gate electrode TXa. The non-silicon photodetector region 105a may be formed at a recess in the silicon substrate 25a where the recess is adjacent to the buffer transistor region T5a. The non-silicon photodetector region 105a may include an insulation portion 125a and a non-silicon material portion surrounded by the insulation portion 125a. The non-silicon material portion may include P-type germanium 135a and N-type germanium 145a formed on the P-type germanium 135a. In other words, the P-type germanium 135a and the N-type germanium 145a may form a PN junction. Thus, the non-silicon photodetector 105 of FIG. 14 may form a PN junction diode.

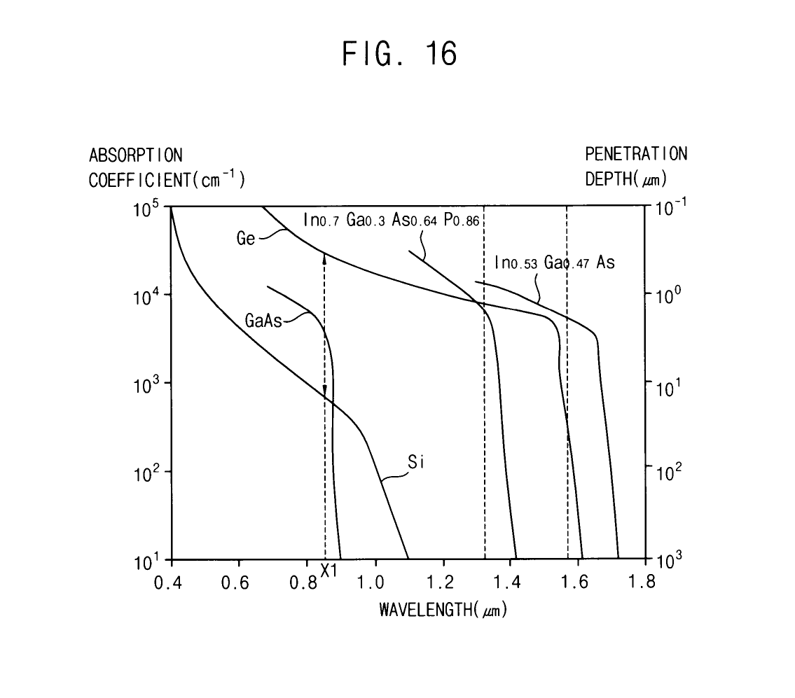

FIG. 16 is a diagram for describing quantum efficiency of non-silicon material.

In FIG. 16, the horizontal reference axis represents a wavelength (μm) of incident light to photosensing materials such as Ge, Si GaAs, In_{(0.7)}Ga_{(0.3)}As_{(0.67)}P_{(0.86)}, In_{(0.53)}Ga_{(0.47)}. As and the vertical reference axis represents a absorption coefficient (1/cm) or a penetration depth (μm).

Referring to FIG. 16, germanium Ge has the higher absorption coefficient or the lower penetration depth with respect to infrared light than silicon Si. With respect to near-infrared light having the wavelength of about 800 nm, germanium Ge has the absorption coefficient about fifty times higher than the absorption coefficient of silicon Si. The higher absorption coefficient corresponds to the higher quantum efficiency. The non-silicon material, i.e., germanium may be used to implement a photodetector having high quantum efficiency.

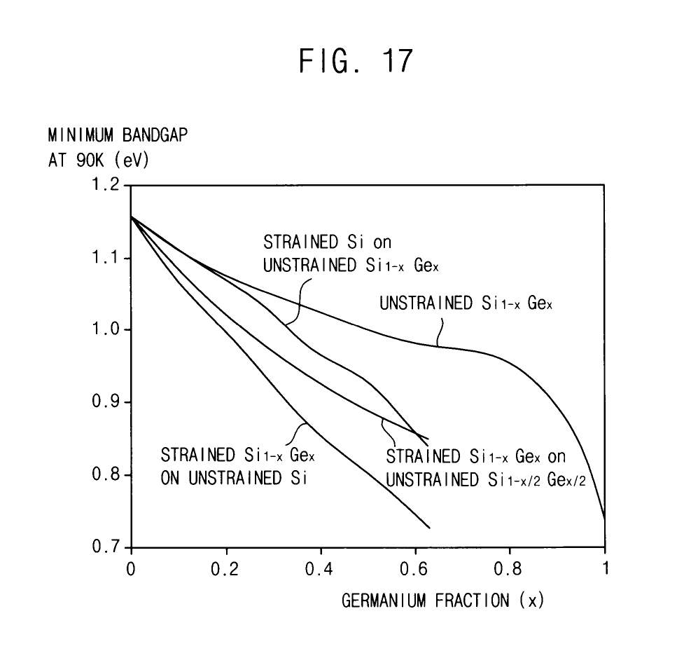

FIG. 17 is a diagram for describing bandgap energy of germanium compound.

In FIG. 17, the horizontal reference axis represents a fraction (x) of germanium and the vertical reference axis represents a minimum bandgap energy (eV) at the absolute temperature 90 K.

Referring to FIG. 17, the bandgap energy is decreased as the germanium fraction is increased in the various strained or unstrained germanium compounds. Even though the germanium fraction is low in the germanium compounds, the bandgap energy may be decreased to the meaningful level. The non-silicon material forming the non-silicon photodetector according to example embodiments may be silicon germanium, strained silicon on silicon germanium, strained silicon germanium on silicon germanium, or strained silicon germanium on silicon.

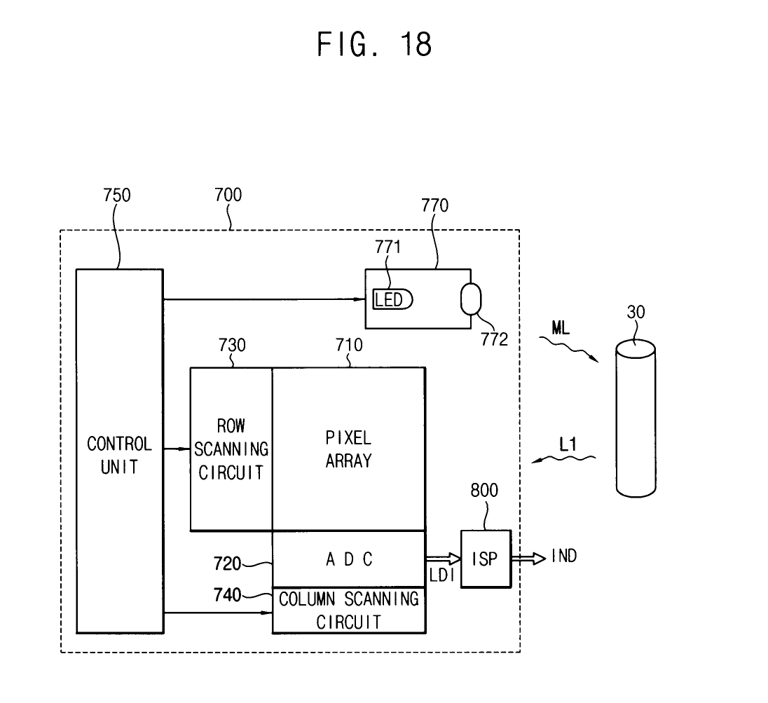

FIG. 18 is a block diagram illustrating a three-dimensional image sensor according to example embodiments.

Referring to FIG. 18, a three-dimensional image sensor 700 may include a pixel array 710, an analog-to-digital conversion (ADC) circuit 720, a row scanning circuit 730, a column scanning circuit 740, a control circuit 750, a light source module 770 and an image signal processor (ISP) 800.

The pixel array 710 may include a plurality of unit pixels, i.e., depth pixels that convert incident light L1 to electric signals where the incident light includes a transmission light ML reflected by an object 30. The depth pixels may provide the electric signals representing depth information or distance information to obtain a distance to the object 30.

As illustrated in FIG. 1, each of the depth pixels in the pixel array 710 may include the non-silicon photodetector 100 and at least one readout circuit 200 as illustrated in FIG. 1. Referring back to FIG. 1, the non-silicon photodetector 100 may be formed at a silicon substrate and include at least one of non-silicon materials to generate photocharge in response to the incident light L1. The non-silicon materials may be germanium, silicon germanium compound, indium gallium arsenide, amorphous silicon germanium compound, black silicon germanium compound, porous silicon germanium compound, germanium antimony telluride, indium gallium antimonide, indium arsenide, mercury cadmium telluride, silicide, transition metal silicide, selenide, telluride, sulfide, etc. For example, the non-silicon material may be silicon germanium compound Si₍₁₋ₓ₎Ge₍ₓ₎ that includes germanium and silicon of x:(1-x) ratio. For another example, the non-silicon material may be indium gallium arsenide In₍ₓ₎Ga₍₁₋ₓ₎As that includes indium and gallium of x:(1-x) ratio. The other compounds having various elements of various ratios may be used to form the non-silicon photodetector 100. Such non-silicon materials may have higher quantum efficiency with respect to infrared light or light having a wavelength between 800 nm and 1400 nm than silicon materials. In some example embodiments, the non-silicon photodetector 100 may be formed at the silicon substrate using photosensitive semiconductor quantum dots.

The incident light L1 may include infrared light or light having a wavelength between 800 nm and 1400 nm. The incident light L1 may be the modulated light that has periodically-varying intensity. The non-silicon photodetector 100 may provide the generated photocharge to the readout circuit 200 through a conduction path 300. The non-silicon photodetector 100 may be coupled to a low power voltage or a ground voltage VSS through a conduction path 190.

The readout circuit 200 may be formed at the silicon substrate and the readout circuit 200 may be configured to output the sensing signal based on the photocharge. The photocharge is where the sensing signal is used for generating depth information or distance information. According to example embodiments, the non-silicon photodetector 100 may be formed at a recess in the silicon substrate where the recess is adjacent to the readout circuit, or the non-silicon photodetector 100 may be formed on the readout circuit 200.

As illustrated in FIG. 1, the readout circuit 200 may include the switching block 210, the readout block 220, and the capacitor Ca. The switching block 210 may provide the charge from the non-silicon photodetector 100 to the capacitor Ca in synchronization with the demodulation signal TXa. The demodulation signal TXa may have a voltage level changing with the time period of the incident light. The capacitor Ca may collect the charge provided through the switching block 210 in response to the demodulation signal TXa. The capacitor Ca may include the first electrode coupled to the low power voltage VSS and the second electrode coupled to the switching block 210 and the readout block 220. The readout block 220 may output the sensing signal to the column line CL in response to the selection signal SELa where the sensing signal corresponds to the voltage VCa of the capacitor Ca, i.e., voltage at the second electrode of the capacitor Ca. The readout block 220 may initialize the voltage VCa of the capacitor Ca in response to the reset signal RST.

The pixel array may further include a plurality of color pixels and the three-dimensional image sensor 700 may provide depth information and color image information. The color pixels may be formed at the silicon substrate between the depth pixels and the number ratio of the depth pixels and the color pixels may be changed variously. The color pixels may convert visible light to color image signals. The visible light may be included in the incident light. The color pixels may have higher quantum efficiency with respect to the visible light than the depth pixels. Color filters such as red filters, green filters and blue filters may be formed over the color pixels and infrared filters or near-infrared filters may be formed over the depth filters.

The ADC circuit 720 may convert analog signals from the pixel array 710 to digital signals to provide first image signals LDI. According to example embodiments, the ADC circuit may perform column ADC that converts analog signals in parallel using a plurality of analog-to-digital converters respectively coupled to a plurality of column lines, or may perform single ADC that converts the analog signals in series using a single analog-to-digital converter.

The ADC circuit 720 may include a correlated double sampling (CDS) unit for extracting an effective signal component (the valid voltage). In some example embodiments, the CDS unit may perform analog double sampling (ADS) that extracts the effective signal component based on an analog reset signal that represents a reset component and an analog data signal that represents a signal component. In other example embodiments, the CDS unit may perform digital double sampling (DDS) that converts the analog reset signal and the analog data signal into two digital signals to extract as the effective signal component a difference between the two digital signals. In still other example embodiments, the CDS unit may perform dual correlated double sampling that performs both of analog double sampling and digital double sampling.

The row scanning circuit 730 may receive control signals from the control circuit 750 to control a row address of the pixel array 710. For example, the row scanning circuit 730 may include a row decoder configured to select a row line among a plurality of row lines of the pixel array 710 and a row driver configured to activate the selected row line.

The column scanning circuit 740 may receive control signals from the control circuit 750 to control a column address of the pixel array 710 to provide the first image signals LDI to the image signal process 800. For example, the column scanning circuit 740 may sequentially select the analog-to-digital converters in the ADC circuit 720 to output the first image signals LDI. The column scanning circuit 740 may include a column decoder configured to select one of the analog-to-digital converters and a column driver configured to transfer the output of the selected analog-to-digital converter.

The control circuit 750 may control the ADC circuit 720, the row scanning circuit 730, the column scanning circuit 740, and the light source module 770. The control circuit 750 may provide respective control signals, i.e., clock signals, timing control signals for operations of the ADC circuit 720, the row scanning circuit 730, the column scanning circuit 740, and the light source module 770. For example, the control circuit 750 may include a control logic, a phased-locked loop, a timing control circuit, a communication interface circuit, etc.

The light source module 770 may emit a modulated transmission light ML having a given, desired, or predetermined wavelength. For example, the light source module 770 may emit infrared light or near-infrared light. The emitted light ML generated by the light source module 770 may be focused on the object 30 by a lens 772. The light source module 770 may be controlled by the control signal from the control circuit 750 to output the modulated transmission light ML such that the intensity of the modulated transmission light ML periodically changes. The modulated transmission light ML may be a pulse wave, a sine wave, a cosine wave, etc. For example, the light source module 770 may be implemented with a light source 771, i.e., a light emitting diode (LED), a laser diode, etc.

Hereinafter, the operation of the three-dimensional image sensor 700 is described. The control circuit 750 controls the light source module 770 to output the modulated transmission light ML having periodically-varying intensity. The modulated transmission light ML is reflected by the object 30 and the reflected light may be included in the incident light L1 input to the pixels in the pixel array 710. The pixels selected by the row scanning circuit 730 output the analog signals corresponding to the incident light L1. The ADC circuit 720 converts the analog signals to the digital signals and the column scanning circuit 740 sequentially select the digital signals to provide the first image signal LDI. The digital signal processor 800 may process the first image signal LDI to provide the depth information IND. In some example embodiments, the pixel array 710 may further include color pixels and the image signal processor 800 may the depth information and the color image information.

As described above, the unit pixel or the depth pixel of the three-dimensional image sensor 700 may include the non-silicon photodetector having the higher quantum efficiency than the silicon photodetector. Thus, the unit pixel or the depth pixel may sense the infrared light with enhanced efficiency. Accordingly the three-dimensional image sensor 700 may provide an image of higher resolution, than the related art image sensor which only includes the silicon photodetector.

FIG. 19 is a diagram for describing an example operation of the unit pixel of

Referring to FIGS. 18 and 19, the three-dimensional image sensor 700 may emit the modulated transmission light ML having the intensity varying periodically. For example, the three-dimensional image sensor 700 may turn on and off the light source 771 with a frequency of 10 through 200 MHz to generate the modulated transmission light ML.

The modulated transmission light ML is reflected by the object 30 and returns to the three-dimensional image sensor 700 as the incident light L1. The incident light L1 is delayed by the time-of-flight TOF with respect to the modulated transmission light ML. As illustrated in FIG. 19, the TOF corresponds to the time interval t2-t1 or t4-t3.

The first demodulation signal TXa may have the phase equal to the phase of the modulated transmission light ML, the second demodulation signal TXb may have the phase opposite to the phase of the modulated transmission light ML. Thus, the first and second demodulation signals TXa and TXb may have a phase difference of 180 degrees. During the integration mode, the buffer control signal Vbb may be activated, for example, to a logic high level, to turn on the buffer unit 505 of FIG. 14. Accordingly a first charge P2 of the photocharge P1 generated in the non-silicon photodetector may be collected in the first capacitor Ca in response to the first demodulation signal TXa and a second charge P3 of the photocharge P1 may be collected in the second capacitor Cb in response to the second demodulation signal TXb. For example, the activation voltage level of the demodulated signals TXa and TXb may be about 3V and the deactivation voltage level of demodulated signals TXa and TXb may be about 0V.

The ratio of the first and second charges P2 and P3 may be changed depending on the TOF. As the TOF increases, the first charge P2 collected by the first capacitor Ca may be decreased and the second charge P3 collected by the second capacitor Cb may be increased. Thus, the three-dimensional image sensor 700 may calculate the TOF, i.e., the delay time of the incident light L1 with respect to the modulated transmission light ML, by measuring the ratio of the charges respectively collected in the first and second capacitors Ca and Cb.

The distance to the object 30 may be calculated based on the obtained TOF. When the distance is D and the speed of the light is c, the distance D may be calculated using the D=(TOF*c)/2. Therefore, as illustrated in FIG. 14, the three-dimensional image sensor 700 may provide the depth information using the unit pixel 15 including the non-silicon photodetector 105 generating the photocharge Pl, the first readout circuit 205 measuring the first charge P2, and the second readout 405 measuring the second charge P3.

During the integration mode, the first switching block 215 may be turned on in response to the first demodulation signal TXa to collect the first charge P2 in the first capacitor Ca and the second switching block 415 may be turned on in response to the second demodulation signal TXb to collect the second charge P3 in the second capacitor C2.

At a first sampling time TSS, the three-dimensional image sensor 700 may sample the sensing signals corresponding to the charges respectively collected in the capacitors Ca and Cb. When the reset signal RST is activated after the first sampling time TSS, the reset voltage or the high power voltage VDD is applied to the capacitors Ca and Cb to initialize the voltages VCa and VCb of the capacitors Ca and Cb. At a second sampling time TRS, the three-dimensional image sensor 700 may sample the initialize signals corresponding to the reset states of the capacitors Ca and Cb. The sensing signals sampled at the time TSS and the initialized signals sampled at the time TRS may be used to perform the correlated double sampling.

FIG. 19 illustrates a non-limiting example using a pulse signal as the modulated transmission light ML and the demodulation signals TXa and TXb. However, various periodic signals such as a sine signal, a cosine signal, etc., may be used as the modulated transmission light ML and the demodulation signals TXa and TXb.

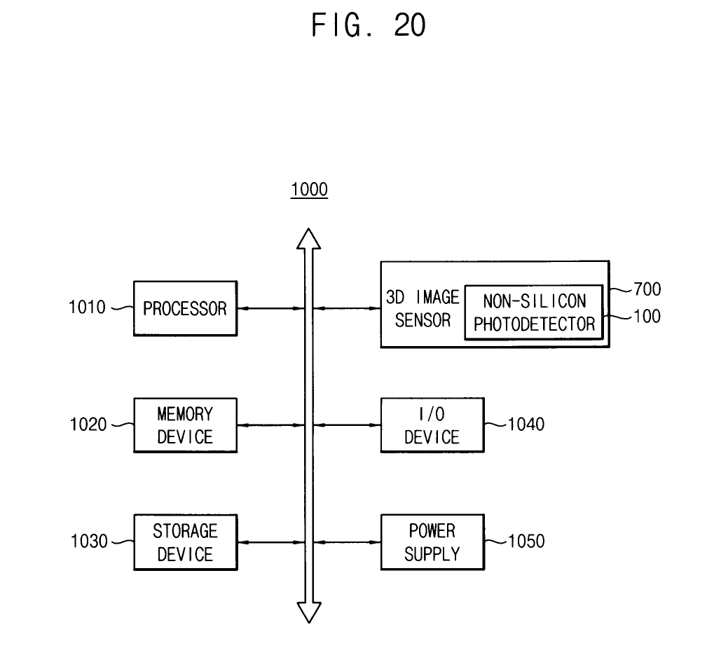

FIG. 20 illustrates a block diagram of an example embodiment of a computer system including a three-dimensional image sensor.

Referring to FIG. 20, a computing system 1000 may include a processor 1010, a memory device 1020, a storage device 1030, an input/output device 1040, a power supply 1050, and a three-dimensional image sensor 700. Although it is not illustrated in FIG. 20, the computing system 1000 may further include ports that communicate with a video card, a sound card, a memory card, a universal serial bus (USB) device, or other electronic devices.

The processor 1010 may perform various calculations or tasks. According to at least some example embodiments, the processor 1010 may be a microprocessor or a CPU. The processor 1010 may communicate with the memory device 1020, the storage device 1030, and the input/output device 1040 via an address bus, a control bus, and/or a data bus. In at least some example embodiments, the processor 1010 may be coupled to an extended bus, such as a peripheral component interconnection (PCI) bus. The memory device 1020 may store data for operating the computing system 1000. For example, the memory device 1020 may include volatile memory such as dynamic random access memory (DRAM), mobile DRAM, and static random access memory (SRAM), and/or non-volatile memory. The non-volatile memory may be electrically erasable programmable read-only memory (EEPROM), flash memory, phase change random access memory (PRAM), resistance random access memory (RRAM), nano floating gate memory (NFGM), polymer random access memory (PoRAM), magnetic random access memory (MRAM), or ferroelectric random access memory (FRAM). The storage device 1030 may include a solid state drive (SSD), a hard disk drive (HDD), a CD-ROM, etc. The input/output device 1040 may include an input device (e.g., a keyboard, a keypad, a mouse, etc.) and an output device (e.g., a printer, a display device, etc.). The power supply 1050 supplies operation voltages for the computing system 1000.

The three-dimensional image sensor 700 may communicate with the processor 1010 via the buses or other communication links. As described above, the three-dimensional image sensor 700 may include the depth pixels and the color pixels to prove the depth information and the color image information.

As described with reference to FIG. 18, the three-dimensional image sensor 700 may include the pixel array 710, the analog-to-digital conversion (ADC) circuit 720, the row scanning circuit 730, the column scanning circuit 740, the control circuit 750, the light source module 770, and the image signal processor (ISP) 800.

The pixel array 710 may include at least one unit pixel or depth pixel configured to convert the incident light L1 to the electric signals. As described with reference to FIG. 1, each unit pixel 10 may include the non-silicon photodetector 100 and at least one readout circuit 200. The non-silicon photodetector 100 may be formed at a silicon substrate and include at least one of non-silicon materials to generate photocharge in response to incident light. The non-silicon materials may be germanium, silicon germanium compound, indium gallium arsenide, amorphous silicon germanium compound, black silicon germanium compound, porous silicon germanium compound, germanium antimony telluride, indium gallium antimonide, indium arsenide, mercury cadmium telluride, silicide, transition metal silicide, selenide, telluride, sulfide, etc. For example, the non-silicon material may be silicon germanium compound Si₍₁₋ₓ₎Ge₍ₓ₎ that includes germanium and silicon of x:(1-x) ratio. For another example, the non-silicon material may be indium gallium arsenide In₍ₓ₎Ga₍₁₋ₓ₎As that includes indium and gallium of x:(1-x) ratio. The other compounds having various elements of various ratios may be used to form the non-silicon photodetector 100. Such non-silicon materials may have higher quantum efficiency with respect to infrared light or light having a wavelength between 800 nm and 1400 nm than silicon materials. In some example embodiments, the non-silicon photodetector 100 may be formed at the silicon substrate using photosensitive semiconductor quantum dots.

The incident light may include infrared light or light having a wavelength between 800 nm and 1400 nm. The incident light may be the modulated light that has periodically-varying intensity. The non-silicon photodetector 100 may provide the generated photocharge to the readout circuit 200 through a conduction path 300. The non-silicon photodetector 100 may be coupled to a low power voltage or a ground voltage VSS through a conduction path 190.

The readout circuit 200 may be formed at the silicon substrate and the readout circuit 200 may be configured to output a sensing signal based on the photocharge, where the sensing signal is used for generating depth information or distance information. According to example embodiments, the non-silicon photodetector 100 may be formed at a recess in the silicon substrate, where the recess is adjacent to the readout circuit, or the non-silicon photodetector 100 may be formed on the readout circuit 200.

The three-dimensional image sensor 700 may be packaged in various forms, i.e., package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The computing system 1000 may be any computing system using a three-dimensional image sensor. For example, the computing system 1000 may include a mobile phone, a smart phone, a personal digital assistant (PDA), a portable multimedia player (PMP), a digital camera, a personal computer (PC), a server computer, a workstation, a notebook, a digital television, a portable game console, a navigation system, a automatic focusing system. a motion sensing system, a face recognition system, etc.

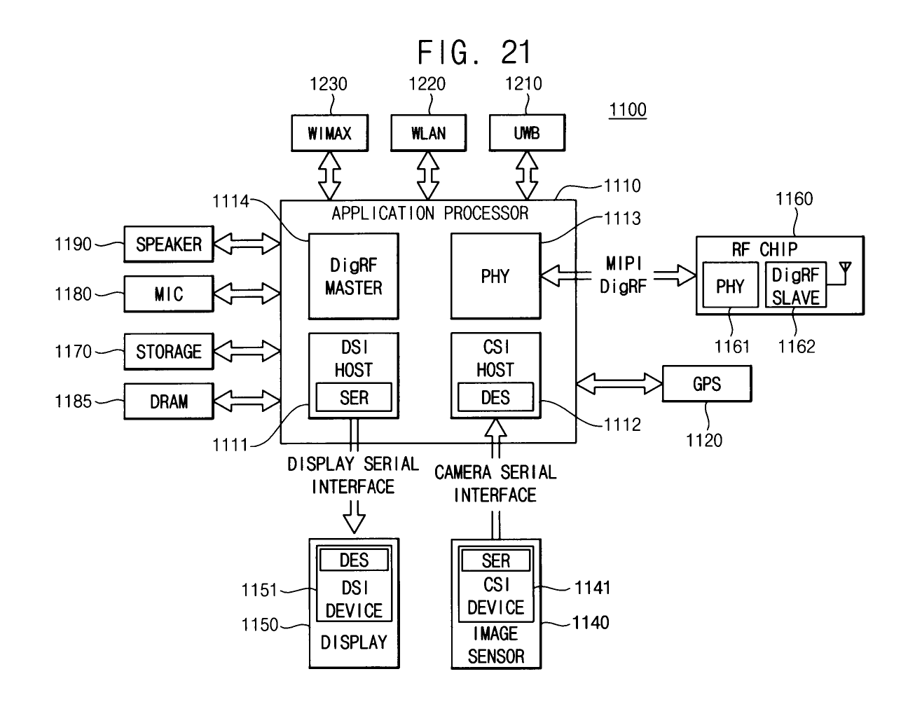

FIG. 21 illustrates a block diagram of an example embodiment of an interface in the computing system of FIG. 20.

Referring to FIG. 21, a computing system 1100 may be implemented by a data processing device that uses or supports a mobile industry processor interface (MIPI) interface. The computing system 1100 may include an application processor 1110, a three-dimensional image sensor 1140, a display device 1150, etc. A camera serial interface (CSI) host 1112 of the application processor 1110 may perform a serial communication with a CSI device 1141 of the three-dimensional image sensor 1140 via a CSI. In some example embodiments, the CSI host 1112 may include a deserializer (DES), and the CSI device 1141 may include a serializer (SER). A DSI host 1111 of the application processor 1110 may perform a serial communication with a DSI device 1151 of the display device 1150 via a display serial interface (DSI).

In some example embodiments, the DSI host 1111 may include a serializer (SER), and the DSI device 1151 may include a deserializer (DES). The computing system 1100 may further include a radio frequency (RF) chip 1160 performing a communication with the application processor 1110. A physical layer (PHY) 1113 of the computing system 1100 and a physical layer (PHY) 1161 of the RF chip 1160 may perform data communications based on a MIPI DigRF. The application processor 1110 may further include a DigRF MASTER 1114 that controls the data communications of the PHY 1161.

The computing system 1100 may further include a global positioning system (GPS) 1120, a storage 1170, a MIC 1180, a DRAM device 1185, and a speaker 1190. In addition, the computing system 1100 may perform communications using an ultra wideband (UWB) 1120, a wireless local area network (WLAN) 1220, a worldwide interoperability for microwave access (WIMAX) 1130, etc. However, the structure and the interface of the electric device 1000 are not limited thereto.

Features and embodiments described herein may be applied to any photo-detection device, i.e., a three-dimensional image sensor providing image information and depth information about an object. For example, one or more example embodiments may be applied to a computing system, i.e., a face recognition security system, a desktop computer, a laptop computer, a digital camera, a three-dimensional camera, a video camcorder, a cellular phone, a smart phone, a personal digital assistant (PDA), a scanner, a video phone, a digital television, a navigation system, an observation system, an auto-focus system, a tracking system, a motion capture system, an image-stabilizing system, etc.

The foregoing is illustrative of example embodiments and is not to be construed as limiting thereof. Although a few example embodiments have been described, those skilled in the art will readily appreciate that many modifications are possible in the exemplary embodiments without materially departing from the novel teachings and advantages. Accordingly, all such modifications are intended to be included within the scope of the embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A unit pixel of a three-dimensional image sensor, comprising:
a non-silicon photodetector formed at a silicon substrate, the non-silicon photodetector comprising at least one of non-silicon materials to generate a photocharge in response to incident light; and
at least one readout circuit formed at the silicon substrate, the at least one readout circuit outputting a sensing signal based on the photocharge, the sensing signal generating depth information on a distance to an object.

2. The unit pixel of claim 1, wherein the non-silicon photodetector is further formed on a doped region in the at least one readout circuit.

3. The unit pixel of claim 2, wherein the non-silicon photodetector is a photoconductor, which comprises intrinsic germanium.

4. The unit pixel of claim 2, wherein the non-silicon photodetector comprises N-type germanium and P-type germanium, and the non-silicon photodetector forms a PN junction diode.

5. The unit pixel of claim 2, wherein the doped region includes N-type silicon, the non-silicon photodetector comprises P-type germanium and intrinsic germanium, and the doped region and the non-silicon photodetector form a PIN junction diode.

6. The unit pixel of claim 1, wherein the non-silicon photodetector comprises at least one of germanium, silicon germanium compound, indium gallium arsenide, amorphous silicon germanium compound, black silicon germanium compound, porous silicon germanium compound, germanium antimony telluride, indium gallium antimonide, indium arsenide, mercury cadmium telluride, silicide, transition metal silicide, selenide, telluride, and sulfide.

7. The unit pixel of claim 1, wherein the non-silicon photodetector comprises photosensitive semiconductor quantum dots.

8. The unit pixel of claim 1, further comprising:
a buffer unit coupled between the non-silicon photodetector and the at least one readout circuit, the buffer unit configured to be turned on and off in response to a buffer control signal.

9. The unit pixel of claim 1, wherein the non-silicon photodetector comprises a first quantum efficiency with respect to infrared light and a second quantum efficiency with respect to visible light, the first quantum efficiency being higher than the second quantum efficiency.

10. The unit pixel of claim 1, wherein the non-silicon photodetector comprises a quantum efficiency with respect to infrared light that is higher than a quantum efficiency of a silicon photodetector.

11. The unit pixel of claim 1, wherein the non-silicon photodetector comprises a quantum efficiency with respect to light of a wavelength between 800 nm and 1100 nm that is higher than a quantum efficiency of a silicon photodetector.

12. The unit pixel of claim 1, wherein the non-silicon photodetector is formed at a recess in the silicon substrate, the recess being adjacent to the at least one readout circuit.

13. The unit pixel of claim 1, wherein the non-silicon photodetector is formed on the at least one readout circuit.

14. A three-dimensional image sensor comprising:
a light source module configured to generate modulated transmission light having periodically-varying intensity;
a pixel array comprising a plurality of unit pixels which convert incident light to electric signals, the incident light including the modulated transmission light reflected by an object; and
an image signal processor which generates depth information based on the electric signals,
wherein one of the plurality of unit pixels comprises:
a non-silicon photodetector formed at a silicon substrate, the non-silicon photodetector comprising at least one of non-silicon materials to generate a photocharge in response to the incident light; and
at least one readout circuit formed at the silicon substrate, the at least one readout circuit outputting a sensing signal based on the photocharge, the sensing signal corresponding to one of the electric signals.

15. The three-dimensional image sensor of claim 14, wherein the pixel array further comprises:
a plurality of color pixels formed at the silicon substrate between the unit pixels, the color pixels converting visible light to color image signals, the visible light included in the incident light, the color pixels comprising a quantum efficiency with respect to the visible light that is higher than a quantum efficiency of the unit pixels.

16. A unit pixel of a three-dimensional image sensor, comprising:
a non-silicon photodetector coupled to a first voltage through a conduction path, the non-silicon photodetector generating a photocharge in response to incident light; and
at least one readout circuit coupled to the non-silicon photodetector through the conduction path, the at least one readout circuit comprises a switching block, a readout block, and a first capacitor, and the at least one readout circuit outputs a sensing signal for generating depth information on a distance to an object, based on the photocharge.

17. The unit pixel of claim 16, wherein the non-silicon photodetector is formed at a silicon substrate.

18. The unit pixel of claim 16, wherein the non-silicon photodetector is formed on a doped region in the at least one readout circuit.

19. The unit pixel of claim 16, wherein the at least one readout circuit is formed at a silicon substrate.

20. The unit pixel of claim 16, wherein the non-silicon photodetector is formed at a recess in a silicon substrate, the recess being adjacent to the at least one readout circuit.

21. The unit pixel of claim 16, wherein the non-silicon photodetector is formed on the at least one readout circuit.

22. The unit pixel of claim 16, wherein a horizontal cross-section of the non-silicon photodetector is decreased gradually along a depth of the horizontal cross-section such that an upper surface of the non-silicon photodetector has a largest area and a bottom surface of the non-silicon photodetector has a smallest area.
